(19) United States
(12) Patent Application Publication
(10) Pub. No.: US 2017/0267899 A1
(43) Pub. Date: Sep. 21, 2017

(54) ELECTRICALLY CONDUCTIVE ADHESIVE TAPES

(71) Applicant: Cima NanoTech Israel Ltd.

(72) Inventors: Jonathan Alton Brodd, Singapore (SG); Chandarasekaran Krishnan, Singapore (SG); Jing Jiang, Singapore (SG); Dov Zamir, Beerotaim (IL)

(21) Appl. No.: 15/101,801

(22) PCT Filed: Oct. 24, 2014
(86) PCT No.: PCT/IB14/65601

§ 371 Date: Jun. 3, 2016

Related U.S. Application Data
(60) Provisional application No. 61/924,862, filed on Jan. 8, 2014.

(51) Int. Cl. C09J 7/02; H05K 9/00; H01B 3/44; H01B 1/22; H01B 13/00

(52) U.S. Cl. CPC C09J 7/0296; H01B 1/22; H01B 13/0036; H01B 3/447; H01B 13/003; H05K 9/0083; C09J 7/0246; C09J 2201/122; C09J 2201/602; C09J 2201/606; C09J 2400/163; C09J 2433/006; C09J 2467/006

(57) ABSTRACT

A process for preparing an electrically conductive, adhesive tape that includes: (a) providing an article comprising a substrate and a network of electrically conductive metal traces defining cells that are transparent to visible light on the substrate; (b) embedding the network of electrically conductive traces in a polymer matrix having a surface on which a pressure sensitive adhesive is deposited; and (c) removing the substrate to form the electrically conductive, adhesive tape.

### CROSS-REFERENCE TO RELATED APPLICATIONS

This application claims the benefit of U.S. Provisional Ser. No. 61/924,862, filed Jan. 8, 2014. The disclosure of the prior application is considered part of (and is incorporated by reference in) the disclosure of this application.

### TECHNICAL FIELD

This invention relates to electrically conductive adhesive tapes.

### BACKGROUND

Electrically conductive adhesive tapes are known and find use in electronic device applications including grounding connections, static dissipation, and EMI shielding. These tapes are often made using conductive particulate fillers (e.g., particles or fibers) in an adhesive matrix, e.g., silver or carbon particles in a pressure sensitive adhesive (PSA) matrix. Other tapes use conductive scrims, e.g., a non-woven carbon scrim, embedded in an adhesive matrix. Useful performance attributes of electrically conductive tapes include sheet resistance, reduced thickness, reduced weight, conformability, form factor, and flexibility. Transparency may also be desirable for some applications.

### SUMMARY

There is described a process for preparing an electrically conductive, adhesive tape that includes: (a) providing an article comprising a substrate and a network of electrically conductive metal traces defining cells that are transparent to visible light on the substrate; (b) embedding the network of electrically conductive metal traces in a polymer matrix having a surface on which a pressure sensitive adhesive is deposited; and (c) removing the substrate to form the electrically conductive, adhesive tape.

In some embodiments, the process includes (a) applying a UV-polymerizable composition onto the network of electrically conductive traces; (b) applying the pressure sensitive adhesive onto the UV-polymerizable composition; and (c) exposing the UV-polymerizable composition to ultraviolet radiation to polymerize the composition and form the polymer matrix in which the network of electrically conductive traces is embedded. In still other embodiments, the process includes (a) applying a UV-polymerizable composition onto the network of electrically conductive traces; (b) exposing the UV-polymerizable composition to ultraviolet radiation to polymerize the composition and form the polymer matrix in which the network of electrically conductive traces is embedded; and (c) applying the pressure sensitive adhesive onto the polymer matrix in which the network of electrically conductive traces is embedded.

Examples of suitable metal traces include traces formed of at least partially joined metal nanoparticles, e.g., silver nanoparticles. In some embodiments, the electrically conductive traces may feature a metal base that has been electroplated with one or more metal layers. For example, the metal traces may feature a silver base electroplated or electrolessly plated with one or more layers of a metal such as copper, tin, or nickel. Electroplating decreases the overall sheet resistance of the electrically conductive adhesive tape. In some embodiments, the pressure sensitive adhesive layer is non-conductive.

Also described is an electrically conductive adhesive tape that includes: (a) a polymer matrix having a first surface and a second surface; (b) a network of electrically conductive metal traces defining cells that are transparent to visible light embedded in the polymer matrix; and (c) a pressure sensitive adhesive deposited onto the second surface of the polymer matrix. The network of electrically conductive metal traces is exposed on the first surface of the polymer matrix.

In some embodiments, the conductive metal traces comprise at least partially joined metal nanoparticles, e.g., silver nanoparticles. The polymer matrix may be a cured (meth)acrylic resin. The visible light transmittance of the tape may be greater than 60%, greater than 70%, or greater than 75%. The sheet resistance of the tape may be less than 10 Ohms/square, less thans than 1 Ohm/square, or less than 0.1 Ohm/square. The overall thickness of the tape may be less than 50 nm, less than 30 nm, or less than 15 nm. The pressure sensitive adhesive layer itself may be non-conductive.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a cross-sectional view of a transparent, electrically conductive tape.

Like reference symbols in the various drawings indicate like elements.

### DETAILED DESCRIPTION

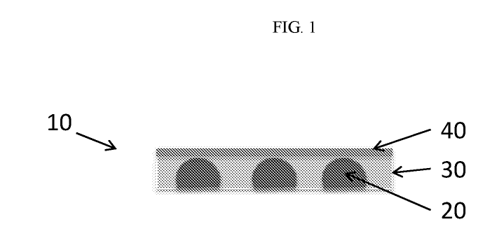

FIG. 1 is a cross-sectional view of a transparent, electrically conductive tape 10. Tape 10 includes a transparent, electrically conductive network 20, a cured resin layer (polymer matrix) 30, and a pressure sensitive adhesive (PSA) layer 40. The PSA layer 40 forms an adhesive surface of the tape. As noted above, “transparent” means transparent to visible radiation. The opposite surface of tape 10 is a planar, electrically conductive surface having the exposed electrically conductive network. The PSA layer 40 can optionally have a release liner for transport and handling. Visible radiation transmittances of the tape can be greater than 60%, preferably greater than 70%, or preferably greater than 75%. Sheet resistances of the tape can be less than 10 Ohms/square, preferably less than 1 Ohm/square, or most preferably less than 0.1 Ohms/square. The overall thickness of the tape can be less than 50 μm, less than 30 μm, or less than 15 μm. The tape can be flexible, e.g., the tape can be rolled into a non-planar configuration without significant loss of conductivity. Flexibility also allows the tape to conform to non-planar surfaces. The tape can be a variety of sizes, ranging from sheets to strips to rolls.

Electrically conductive network 20 is a transparent, electrically conductive network of metal traces. The network of metal traces can be continuously conductive to electricity and defines cells that are transparent to visible light, i.e. visible radiation. Shapes (e.g. patterns) of the network and cells defined by the network may be regular, irregular, or random. Useful networks can be formed from metal, e.g. silver, nanoparticles that self-assemble into a transparent, conductive network of traces and cells, as described in U.S. Pat. No. 7,601,406, which is hereby incorporated by reference. Such networks comprise traces formed of at least partially joined metal nanoparticles to provide electrical conductivity. Other useful electrically conductive networks include networks deposited from conductive inks using printing processes, networks formed by patterned exposure of silver halide emulsions to radiation and subsequent development, and networks formed from the deposition of conductive particles into preformed patterns of grooves in a substrate.

The network can be formed on a polymeric substrate, such as polyester film (e.g. PET), which can be a sacrificial substrate for the transfer process described in US Patent Application Publication 2011/0273085, which is assigned to the same assignee as the present application and incorporated by reference. Examples of commercially available, transparent, electrically conductive network films are Sante FS100 EMI Shielding Film and Sante FS200 Touch Film (Cima NanoTech, St. Paul, Minn.). Once formed, the conductive network can be further electroplated or electrolessly plated with a conductive metal to reduce sheet resistances as described in U.S. Pat. No. 8,105,472 and US Patent Application Publication 2011/0003141, both of which are assigned to same assignee as the present application and hereby incorporated by reference. Examples of suitable electroplated or electrolessly plated conductive metals include copper, nickel, or tin. An example of a commercially available electroplated conductive network film is FS100-LR-1N EMI Shielding Film (Cima NanoTech. St. Paul, Minn.). Electroless plating can be performed by immersing the substrate and conductive network into common electroless plating baths, such as those containing Solderon ST300 available from Rohm and Haas Electronic Materials. Electroplating and electroless plating of the conductive network can also facilitate the process of transferring the network from the original substrate to a new substrate, as described below.

The electrically conductive network 20 is embedded in cured resin layer (polymer matrix) 30 except for the surface of the conductive network attached to the sacrificial substrate, which will later be exposed and can be generally coplanar with the surface of the cured resin layer. The cured resin layer can be formed from a curable (e.g. polymerizable) resin capable of being coated onto the conductive network and supporting substrate, followed by curing to form the cured resin layer. Desirable properties of the cured resin layer include the ability to form a self-supporting (e.g., free-standing) film, flexibility, conformability, stretchability (i.e. the film is elastomeric), adhesion to the conductive network and PSA layer, transparency, and a non-tacky surface after curing. Preferred polymerizable resins are photocurable resins, e.g. resins having photoinitiators and curable using visible or UV wavelengths. Acrylic and methacrylic (collectively “(meth)acrylic”) resins or combinations thereof, can be used to form the cured resin layer, an example of which is Unidic V 9510 acrylic resin (DIC Corp., Parsippany, N.J.). The thickness of the cured resin layer can be less than 30 μm, less than 20 μm, or less than 10 μm.

The PSA layer 40 can be formed from a variety of pressure sensitive adhesives. PSAs can be supplied as preformed adhesives on release films and ready for lamination, or they can be formed from solutions coated onto the cured resin layer. The thickness of the PSA layer can be less than 30 μm, less than 20 μm, or less than 10 μm. The PSA layer is preferably transparent to visible light. Preferred PSAs are ones commonly intended for use in electronic devices, an example of which is 3M Double Coated Tape 9019 (3M, St. Paul, Minn.).

The process of forming the conductive tape 10 includes the steps of providing the transparent, conductive network on a sacrificial substrate, coating or laminating the curable resin layer, e.g. a UV-polymerizable composition, onto the surface of the sacrificial substrate having the conductive network, coating or laminating the PSA layer onto the curable resin layer, curing the curable resin layer, and removing the sacrificial substrate to form the finished conductive tape. Optionally, the curable resin layer can be cured prior to the step of laminating the PSA layer.

Lamination steps can use common lamination techniques such as pressure and/or heat. Curing of the curable resin layer preferably is done using a photocurable resin and visible or UV irradiation. If done prior to PSA coating, irradiation can be from either the surface having the curable resin or the opposite surface, i.e. irradiating through the sacrificial substrate, which can be transparent to wavelengths being used. If done after PSA coating, the irradiation can preferably be done through the sacrificial substrate rather than from the PSA surface. Throughout the processing steps, commonly used carrier films, protective films, and release films can be used to facilitate processing, e.g. roll-to-roll processing.

The conductive tape described herein can be useful in a variety of electronic devices and applications. Examples include EMI shielding, antennas, and providing a grounding pathway or making electrical connections. In use, a piece of the conductive tape is cut to the desired size, the adhesive surface of the tape is pressed onto the electronic part or device, and an electrical connection is made with the exposed, non-tacky surface of the tape using common techniques such as conductive foils or solder. For some applications, e.g., antennas, a pattern can be formed on the conductive network before or after attachment to the electronic device using common techniques such as laser ablation or chemical etching.

### EXAMPLE

A piece of transparent, conductive film formed from self-assembling silver nanoparticles on a PET substrate (Sante FS200 Touch Film available from Cima NanoTech, St. Paul, Minn.) approximately 13×23 cm was electroplated using a two-step process. First, electrolytic copper plating was done by connecting electrodes to the sample, then immersing the sample in a bath comprising Copper Gleam 125T-2 (Rohm and Haas Electronic Materials, Marlborough, Mass.) and using the manufacturer's instructions. The plating was done at room temperature at 0.1 A for 20 minutes, followed by 0.5 A for 25 minutes. A second plating step to mask the reddish tint of the copper plating was done using electrolytic nickel plating in a bath comprising Nickal PC-3 (Rohm and Haas Electronic Materials) and using the manufacturer's instructions. The plating was done at room temperature using 0.1 A for 20 minutes.

The electroplated film was next coated with a UV curable resin (Unidic V 9510 acrylic resin available from DIC Corp., Parsippany, N.J.) on the surface having the conductive network to a wet thickness of 24 um. A pressure sensitive adhesive (3M Double Coated Tape 9019 available from 3M, St. Paul, Minn.) was next laminated to the UV resin coating using a GHQ-320 PR3 laminator at 300 mm/min., leaving the release liner attached on the exposed adhesive side of the PSA. The UV resin layer was cured in a Fusion UV curing system (Fusion UV Systems, Gaithersburg, Md.), H bulb, at 6 feet/minute, power approximately 0.207 J/cm2. Curing was done through the PET substrate (i.e. the surface of the layered film opposite from the surface having the PSA layer was exposed to the UV radiation). Once curing was complete, the PET substrate was peeled away, thus exposing the surface having the conductive network.

The resulting film was flexible, i.e. it could be rolled up and unrolled without a change in sheet resistance. The film was tested and had a sheet resistance of 0.04-0.05 Ohms/square (Loresta-GP MCP T610 4 point probe, available from Mitsubishi Chemical, Chesapeake, Va.). Transmittance was 73%, tested using a Nippon Denshoku (Japan) haze meter, model NDH5000 using ASTM 1003.

A number of embodiments of the invention have been described. Nevertheless, it will be understood that various modifications may be made without departing from the spirit and scope of the invention. Accordingly, other embodiments are within the scope of the following claims.

What is claimed is:

1. A process for preparing an electrically conductive, adhesive tape comprising:
(a) providing an article comprising a substrate and a network of electrically conductive metal traces defining cells that are transparent to visible light on the substrate;
(b) embedding the network of electrically conductive traces in a polymer matrix having a surface on which a pressure sensitive adhesive is deposited; and
(c) removing the substrate to form the electrically conductive, adhesive tape.

2. The process of claim 1, comprising:
(a) applying a UV-polymerizable composition onto the network of electrically conductive traces;
(b) applying the pressure sensitive adhesive onto the UV-polymerizable composition; and
(c) exposing the UV-polymerizable composition to ultraviolet radiation to polymerize the composition and form the polymer matrix in which the network of electrically conductive traces is embedded.

3. The process of claim 1, comprising:
(a) applying a UV-polymerizable composition onto the network of electrically conductive traces;
(b) exposing the UV-polymerizable composition to ultraviolet radiation to polymerize the composition and form the polymer matrix in which the network of electrically conductive traces is embedded; and
(c) applying the pressure sensitive adhesive onto the polymer matrix in which the network of electrically conductive traces is embedded.

4. The process of claim 1, wherein the metal traces comprise a metal base and at least one electroplated or electrolessly plated metal layer over the metal base.

5. The process of claim 1, wherein the traces comprise at least partially joined metal nanoparticles.

6. An electrically conductive adhesive tape prepared according to the method of claim 1.

7. An electrically conductive adhesive tape comprising:
(a) a polymer matrix having a first surface and a second surface;
(b) a network of electrically conductive metal traces defining cells that are transparent to visible light embedded in the polymer matrix; and
(c) a pressure sensitive adhesive deposited onto the second surface of the polymer matrix,
wherein the network of electrically conductive metal traces is exposed on the first surface of the polymer matrix.

8. An electrically conductive adhesive tape according to claim 7 wherein the conductive metal traces comprise at least partially joined metal nanoparticles.

9. An electrically conductive adhesive tape according to claim 8 wherein the metal nanoparticles comprise silver nanoparticles.

10. An electrically conductive adhesive tape according to claim 7 wherein the polymer matrix comprises a cured (meth)acrylic resin.

11. An electrically conductive adhesive tape according to claim 7 wherein the visible light transmittance of the tape is greater than 60%.

12. An electrically conductive adhesive tape according to claim 7 wherein the visible light transmittance of the tape is greater than 70%.

13. An electrically conductive adhesive tape according to claim 7 wherein the visible light transmittance of the tape is greater than 75%.

14. An electrically conductive adhesive tape according to claim 7 wherein the sheet resistance of the tape is less than 10 Ohms/square.

15. An electrically conductive adhesive tape according to claim 7 wherein the sheet resistance of the tape is less than 1 Ohm/square.

16. An electrically conductive adhesive tape according to claim 7 wherein the sheet resistance of the tape is less than 0.1 Ohm/square.

17. An electrically conductive adhesive tape according to claim 7 wherein the overall thickness of the tape is less than 50 μm.

18. An electrically conductive adhesive tape according to claim 7 wherein the overall thickness of the tape is less than 30 μm.

19. An electrically conductive adhesive tape according to claim 7 wherein the overall thickness of the tape is less than 15 μm.
